(19) United States
(12) Patent Application Publication
(10) Pub. No.: US 2011/0101392 A1
(43) Pub. Date: May 5, 2011

(54) PACKAGE SUBSTRATE FOR OPTICAL ELEMENT AND METHOD OF MANUFACTURING THE SAME

(76) Inventors: Sung Keun Park, Gyunggi-do (KR); Seog Moon Choi, Seoul (KR); Young Ki Lee, Gyunggi-do (KR); Chang Hyun Lim, Seoul (KR)

(21) Appl. No.: 12/642,326

(22) Filed: Dec. 18, 2009

(30) Foreign Application Priority Data
Nov. 2, 2009 (KR) 10-2009-0105099

(51) Int. Cl. H01L 33/00; H01L 21/56

(52) U.S. Cl. 257/98; 438/27; 257/E33.056; 257/E21.502

(57) ABSTRACT

Disclosed is a package substrate for an optical element, which includes a metal core having a hole formed therein, an insulating layer formed on the surface of the metal core, a first metal layer formed to a predetermined thickness on the surface of the insulating layer so as to include therein the metal core insulated by the insulating layer, an optical element mounted on the first metal layer, and a fluorescent resin material applied on the optical element in order to protect the optical element, thereby simplifying a package substrate process and improving light uniformity, light reflectivity and heat dissipating properties compared to a conventional configuration. A method of manufacturing the package substrate is also provided.

### CROSS REFERENCE TO RELATED APPLICATION

This application claims the benefit of Korean Patent Application No. 10-2009-0105099, filed Nov. 2, 2009, entitled “Package substrate for optical element and manufacturing method thereof”, which is hereby incorporated by reference in its entirety into this application.

### BACKGROUND OF THE INVENTION

1. Technical Field

The present invention relates to a package substrate for an optical element and a method of manufacturing the same.

2. Description of the Related Art

Recently, light emitting diodes (LEDs) are continuously increasing in demand and are gradually receiving attention from the general illumination market, because they are environmentally friendly and achieve energy saving effects including lower power consumption, higher performance, longer operating lifespan, etc., compared to conventional optical elements such as incandescent or fluorescent lamps.

Furthermore, because such an LED may exhibit higher image quality compared to a cold cathode fluorescent lamp conventionally used as a light source of a liquid crystal display, products using it as a backlight unit are being introduced one after another.

A printed circuit board (PCB) or printed wiring board (PWB) for the backlight unit is a thin substrate on which electrical components including integrated circuits, resistors or switches are soldered, and circuits used in most types of computers or a variety of displays are mounted on the PCB.

Upon fabrication of a package substrate for the backlight unit, a fluorescent material is typically applied to emit white light. As such, in the case where the size or thickness of chips has increased, there may occur a phenomenon in which the shape of the applied fluorescent material is not maintained in the form of a dome.

With the goal of solving this problem, a thickness difference is created using metal at the portion of a PCB on which an LED will be mounted.

Although the dome shape of the fluorescent resin material may be maintained by the thickness difference, it is impossible to form a circuit around the chip-mounted portion, and thus a via hole should be additionally formed in a region of the substrate on which the LED is mounted, in order to realize an electrical connection.

Accordingly, a plugging process for filling the via hole with epoxy is additionally performed. Upon filling of the via hole, reliability of epoxy is lowered because of it being applied in a void.

Also, upon mounting of the LED, there may occur process problems in which the LED is tilted by the via hole or in which the die-attach adhesive used to adhere the LED infiltrates the via hole.

Hence, there is required a novel package substrate for an optical element, which enables the electrical connection of an LED by creating a thickness difference to the portion of the substrate on which the LED will be mounted, without a need to form the via hole in the region of the substrate on which the LED is mounted.

### SUMMARY OF THE INVENTION

Accordingly, the present invention has been made keeping in mind the problems encountered in the related art and the present invention is intended to provide a package substrate for an optical element, in which a trench is formed around a region of a metal layer on which the optical element is mounted, thus forming a thickness difference which enables the shape of a fluorescent resin material applied on the optical element to be easily maintained, and also to provide a method of manufacturing the same.

Also the present invention is intended to provide a package substrate for an optical to element, in which a region on which the optical element is mounted is integrated with one of the regions on which electrodes for electrically connecting the optical element are formed, thus obviating a need to form a via hole for an electrical connection in a region of a substrate on which the optical element is mounted, and also to provide a method of manufacturing the same.

An aspect of the present invention provides a package substrate for an optical element, including a metal core having a hole formed therein, an insulating layer formed on a surface of the metal core, a first metal layer formed on a surface of the insulating layer so as to include therein the metal core insulated by the insulating layer, an optical element mounted on the first metal layer, and a fluorescent resin material applied on the optical element in order to protect the optical element.

In this aspect, the package substrate may further include a second metal layer formed on the first metal layer in order to increase reflectivity of light emitted from the optical element.

In this aspect, the package substrate may further include a lens part formed on the fluorescent resin material in order to protect the optical element.

In this aspect, the metal core may include aluminum (Al), an aluminum alloy, or copper (Cu).

In this aspect, the insulating layer may include either aluminum oxide (Al₂O₃) or epoxy.

In this aspect, the first metal layer may include a wiring pattern on which the optical element is mounted, a first electrode pattern integrated with the wiring pattern so as to be electrically connected to the optical element, and a second electrode pattern insulated from the wiring pattern so as to be electrically connected to the optical element.

Also, the first metal layer may further include a trench formed around the wiring pattern so as to form a thickness difference around the wiring pattern.

Another aspect of the present invention provides a method of manufacturing the package substrate for an optical element, including (A) forming a hole in a metal core, (B) forming an insulating layer on a surface of the metal core having the hole formed therein, (C) forming a first metal layer on a surface of the insulating layer to include a trench and a circuit layer composed of a wiring pattern, a first electrode pattern and a second electrode pattern so as to include therein the metal core insulated by the insulating layer, and (D) mounting the optical element on the circuit layer and then applying a fluorescent resin material on the optical element.

In this aspect, the method may further include (E) forming a second metal layer on the first metal layer.

In this aspect, the method may further include (F) forming a lens part on the fluorescent resin material in order to protect the optical element.

In this aspect, (B) may be performed by anodizing the surface of the metal core thus forming the insulating layer on the surface of the metal core.

In this aspect, (B) may be performed by adhering epoxy on the surface of the metal core using an adhesive thus forming the insulating layer on the surface of the metal core.

In this aspect, (C) may include (C-1) forming a seed layer on the surface of the insulating layer using nickel (Ni), titanium (Ti), zinc (Zn), chromium (Cr) or copper (Cu), and then applying copper (Cu) on the seed layer thus forming the first metal layer, and (C-2) bringing a dry film resist into close contact with the first metal layer, performing exposure and development, and then performing primary etching such that a region of the first metal layer around the wiring pattern is half-etched to create the trench, thus forming the circuit layer comprising the wiring pattern, the first electrode pattern and the second electrode pattern which are integrated with each other.

Also, (C-2) may further include performing secondary etching for etching a portion of the first metal layer until the insulating layer is exposed so that at least one of the first electrode pattern and the second electrode pattern is insulated from the wiring pattern.

In this aspect, (D) may include mounting the optical element on the wiring pattern, flip-chip bonding the wiring pattern to an electrode located on a lower surface of the optical element, wire-bonding the at least one of the first electrode pattern and the second electrode pattern, which is insulated from the wiring pattern, to an electrode located on an upper surface of the optical element, and applying the fluorescent resin material on the optical element in order to protect the optical element.

### BRIEF DESCRIPTION OF THE DRAWINGS

The features and advantages of the present invention will be more clearly understood from the following detailed description taken in conjunction with the accompanying drawings, in which:

FIG. 1 is a cross-sectional view showing a package substrate for an optical element according to an embodiment of the present invention; and

FIGS. 2A to 2I are cross-sectional views sequentially showing a process of manufacturing the package substrate for an optical element according to the embodiment of the present invention.

### DESCRIPTION OF SPECIFIC EMBODIMENTS

Hereinafter, embodiments of the present invention will be described in detail while referring to the accompanying drawings. Throughout the drawings, the same reference numerals are used to refer to the same or similar elements. Moreover, descriptions of known techniques, even if they are pertinent to the present invention, are regarded as unnecessary and may be omitted in so far as they would make the characteristics of the to invention and the description unclear.

Furthermore, the terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept implied by the term to best describe the method he or she knows for carrying out the invention.

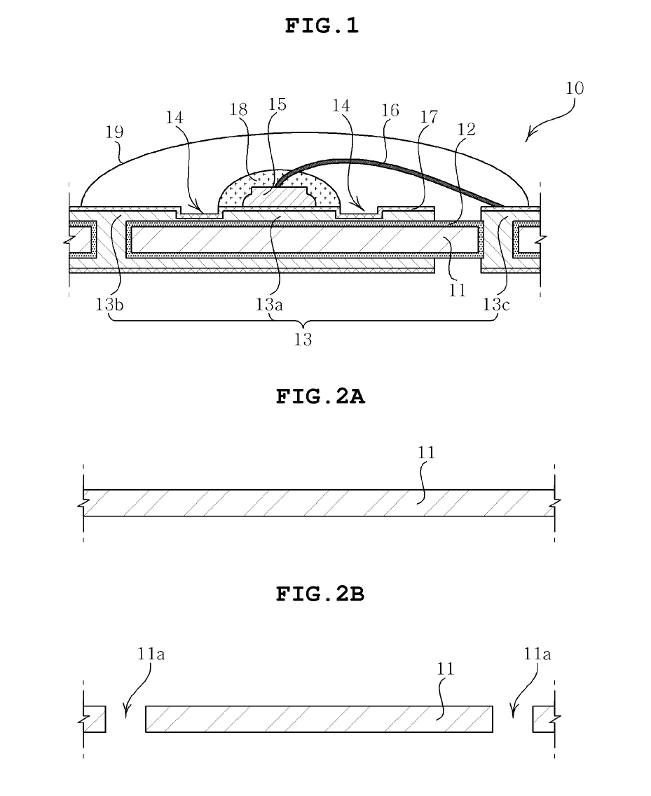

FIG. 1 is a cross-sectional view showing a package substrate for an optical element according to an embodiment of the present invention.

With reference to FIG. 1, the package substrate 10 for an optical element according to the present embodiment includes a metal core 11 having holes formed therein, an insulating layer 12 formed on the surface of the metal core 11, a first metal layer 13 formed to a predetermined thickness on the insulating layer 12, an optical element 15 mounted on the first metal layer 13, and a fluorescent resin material 18 for protecting the optical element 15.

The metal core 11 is made of a metallic material having high heat dissipating properties, for example, aluminum (Al), an aluminum alloy or copper (Cu).

The metal core 11 has through holes of a desired size formed therein by a mechanical process such as drilling

The insulating layer 12 is formed on the entire surface of the metal core 11.

The insulating layer 12 may be an oxide film (e.g. aluminum oxide (Al₂O₃)) resulting from anodizing the metal core 11, or may be made of an insulating material formed by adhering a resin material such as epoxy thereon using an adhesive.

The first metal layer 13 is formed on both surfaces of the insulating layer 12 in order to mount the optical element 15 on the metal core 11 insulated by the insulating layer 12.

The first metal layer 13 includes a seed layer (not shown) made of nickel (Ni), titanium (Ti), zinc (Zn), chromium (Cr) or copper (Cu), and a metal layer (e.g. a copper (Cu) layer) formed to a predetermined thickness on the seed layer.

The thickness of the first metal layer 13 may be set to about 20 μm or more starting to count from the insulating layer 12, the thickness being made taking into consideration the depth of a trench 14 which will be described later.

Furthermore, the first metal layer 13 includes, on one surface thereof, a circuit layer composed of a wiring pattern 13a on which the optical element 15 is mounted and first and second electrode patterns 13b, 13c which are electrically connected to the optical element 15.

This circuit layer may be formed by depositing a dry film resist (DRF) on the first metal layer 13, and performing a PCB circuit patterning process including a series of procedures of exposure, development and etching to obtain a desired circuit pattern, which is known to those skilled in the art and the detailed description of which is omitted.

Also, the trench 14 is formed around the region of the first metal layer 13 on which the optical element 15 will be mounted, namely, around the wiring pattern 13a, so as to facilitate the application of the fluorescent resin material 18 on the optical element 15 and to reduce the spreadability of the fluorescent resin material 18 to thus easily maintain the shape thereof.

Upon etching, the trench 14 is formed such that the bottom surface of the trench 14 is positioned by a predetermined distance from the insulating layer 12.

The depth of the trench 14 is proportional to the thickness of the first metal layer 13, but may be set to about 10 μm or less.

The first electrode pattern 13b formed on the first metal layer 13 according to the PCB circuit patterning process is integrated with the wiring pattern 13a on which the optical element 15 is mounted.

The first electrode pattern 13b thus formed may be electrically connected to the optical element 15 via flip-chip bonding between the electrode located on the lower surface of the optical element 15 and the electrode formed on the wiring pattern 13a.

Also, the second electrode pattern formed on the first metal layer 13 according to the PCB circuit pattering process may result from etching both surfaces of a portion of the first metal layer 13 until the insulating layer 12 is exposed, so as to be insulated from the wiring pattern 13a on which the optical element 15 is mounted.

The second electrode pattern 13c thus formed may be wire-bonded to the electrode located on the upper surface of the optical element 15 using wire 16, and thus be electrically connected to the optical element 15.

An example of the optical element 15 may include a light emitting diode (LED).

Also, the package substrate 10 for an optical element according to the present embodiment may further include a second metal layer 17 formed on the first metal layer 13.

The second metal layer 17 is used to increase reflectivity of light emitted from the optical element 15, and is made mainly of silver (Ag) having superior light radiating properties.

Also, the package substrate 10 for an optical element according to the present embodiment may further include a lens part 19 formed on the fluorescent resin material 18 so as to protect both the optical element 15 mounted on the first metal layer 13 and the region wire-bonded with the optical element 15.

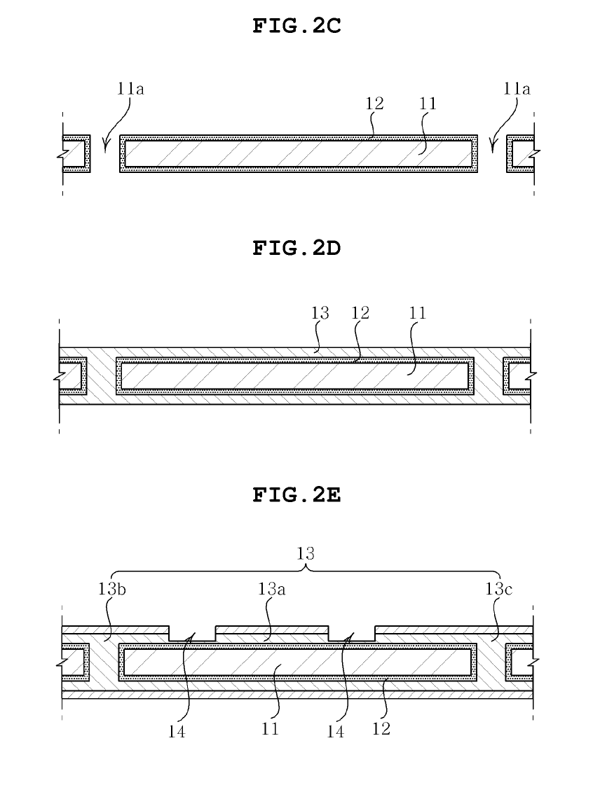

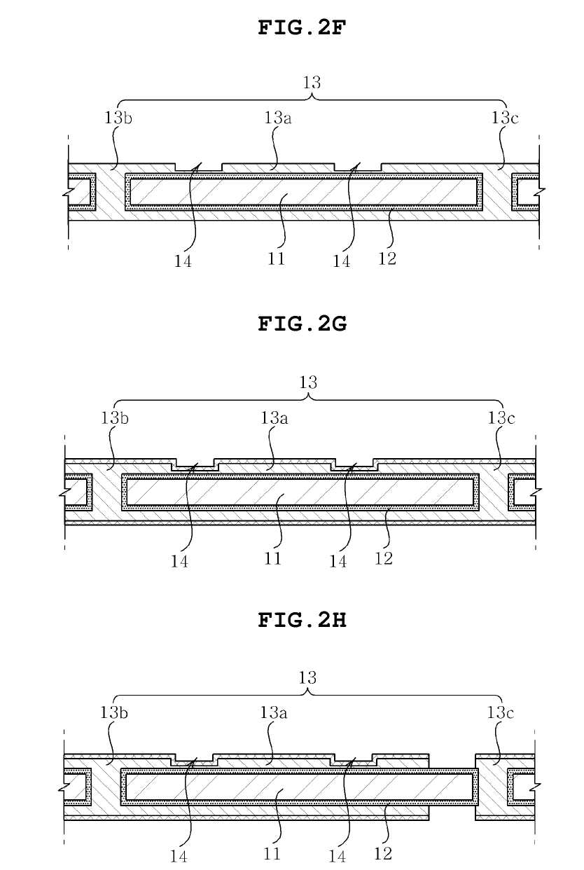

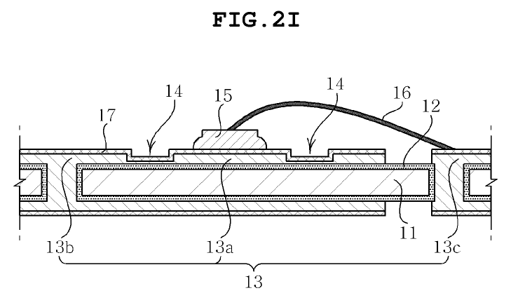

FIGS. 2A to 2I sequentially show a process of manufacturing the package substrate 10 for an optical element according to the embodiment of the present invention.

As shown in FIG. 2A, a metal core 11 is prepared.

Next, as shown in FIG. 2B, through holes of a desired size are formed in the metal core 11 using a mechanical process such as drilling.

Next, as shown in FIG. 2C, an insulating treatment process for forming an insulating layer 12 on the surface of the metal core 11 to thus manufacture an insulating substrate is performed.

The insulating treatment process may include anodizing treatment for anodizing the surface of the metal core 11, and the insulating layer 12 thus formed may typically include aluminum oxide (Al₂O₃).

Alternatively, in lieu of the anodizing treatment, an adhesion process for adhering a resin material such as epoxy on the surface of the metal core 11 using an adhesive may be performed, thus forming the insulating layer 12.

Next, as shown in FIG. 2D, a first metal layer 13 is formed on both surfaces of the insulating layer 12 so as to include therein the metal core 11 insulated by the insulating layer 12.

The first metal layer 13 may be formed by depositing nickel (Ni), titanium (Ti), zinc (Zn), chromium (Cr) or copper (Cu) on the surface of the insulating layer 12 through electroless plating or sputtering thus forming a seed layer, on which copper (Cu) is then deposited to a predetermined thickness using electroplating or sputtering.

When the copper (Cu) is deposited to a predetermined thickness using electroplating or sputtering, the thickness thereof is set to about 20 μm or more starting to count from the insulating layer 12, in consideration of the formation of a trench 14.

Next, as shown in FIG. 2E, a dry film resist is brought into close contact with both surfaces of the first metal layer 13, after which a PCB circuit patterning process including exposure, development and primary etching is performed on either surface on which the optical element 15 will be mounted in order to obtain a desired circuit pattern.

The circuit patterns formed using the PCB circuit patterning process include a wiring pattern 13a on which the optical element 15 will be mounted and first and second electrode patterns 13b, 13c which will be electrically connected to the optical element 15.

Also, when the PCB circuit patterning process is performed, the trench 14 is formed around the wiring pattern 13a of the first metal layer 13 on which the optical element 15 will be mounted.

Upon primary etching for forming the trench 14, half-etching is carried out such that the bottom surface of the trench 14 is positioned by a predetermined distance from the insulating layer 12.

Subsequently, the remaining dry film resist is removed. Then, as shown in FIG. 2F, the first metal layer 13 is configured such that the circuit layer composed of the wiring pattern 13a and the first and second electrode patterns 13b, 13c is integrated with the trench 14.

Subsequently, a second metal layer 17 may be further plated on the first metal layer 13 including the circuit layer 13a˜13c and the trench 14.

Next, as shown in FIG. 2H, the first metal layer 13 is subjected to secondary etching so that either of the first and second electrode patterns 13b, 13c integrated with the wiring pattern 13a is insulated from the wiring pattern 13a.

Upon secondary etching, both surfaces of the first metal layer 13 to be etched are etched until the insulating layer 12 is exposed.

In FIG. 2H, the second electrode pattern 13c is insulated from the wiring pattern 13a.

Next as shown in FIG. 21, the optical element 15 is mounted on the wiring pattern 13a, after which flip-chip bonding and wire-bonding are performed in order to electrically connect the optical element 15.

Specifically, the electrode located on the lower surface of the optical element 15 and the wiring pattern 13a integrated with the first electrode pattern 13b are flip-chip bonded to each other using a solder ball, and the electrode located on the upper surface of the optical element 15 and the second electrode pattern 13c are wire-bonded to each other using wire 16, whereby the optical element 15 and the first and second electrode patterns 13b, 13c are electrically connected to each other.

Subsequently, a fluorescent resin material 18 is applied in order to protect the optical element 15.

As such, because of a thickness difference caused by the trench 14 formed around the wiring pattern 13a, it is easy to apply the fluorescent resin material 18 on the wiring pattern 13a on which the optical element 15 is mounted and to maintain its shape.

Subsequently, formation of a lens part 18 for protecting both the region on which the optical element 15 is mounted and the wire-bonded region may be further performed.

This package substrate for an optical element excludes a via hole which is formed in a region of a substrate on which the optical element is mounted so as to achieve an electrical connection to the lower surface of the optical element.

Accordingly, additional plugging for filing such a via hole with epoxy may be omitted, and a reduction in reliability of epoxy because of it being applied in a void does not occur.

Furthermore, upon mounting of the optical element, the process problems in which the mounted optical element is tilted by the via hole or in which the die-attach adhesive used to adhere the optical element infiltrates the via hole do not occur.

Furthermore, the package substrate for an optical element according to the present invention is advantageous because it is easy to apply the fluorescent resin material and the spreading of the fluorescent resin material is also reduced, thus easily maintaining the shape thereof, because of a thickness difference caused by the trench formed around the region on which the optical element is mounted.

Also, the metal area of the package substrate according to the present invention becomes greater than that of a conventional package substrate for an optical element, thus realizing high reflectivity thanks to surface silver plating treatment.

As described hereinbefore, the present invention provides a package substrate for an optical element and a method of manufacturing the same. According to the present invention, there is no need to form a via hole in a region of a substrate on which the optical element is mounted, resulting in a simple configuration, a simple process and high reliability.

Also, according to the present invention, because of a thickness difference caused by a trench formed around the region of the substrate on which the optical element is mounted, the spreadability of a fluorescent resin material is reduced, so that light uniformity is effectively improved.

Also, according to the present invention, the substrate which mounts the optical element includes a metal core, thus exhibiting superior heat radiating properties, and furthermore, the metal area thereof is enlarged compared to a conventional configuration, thereby improving reflectivity of light emitted from the optical element.

Although the embodiments of the present invention regarding the package substrate for an optical element and the method of manufacturing the same have been disclosed for illustrative purposes, those skilled in the art will appreciate that a variety of different modifications, additions and substitutions are possible, without departing from the scope and spirit of the invention as disclosed in the accompanying claims. Accordingly, such modifications, additions and substitutions should also be understood as falling within the scope of the present invention.

What is claimed is:

1. A package substrate for an optical element, comprising:
a metal core having a hole formed therein;
an insulating layer formed on a surface of the metal core;
a first metal layer formed on a surface of the insulating layer so as to include therein the metal core insulated by the insulating layer;
an optical element mounted on the first metal layer; and
a fluorescent resin material applied on the optical element in order to protect the optical element.

2. The package substrate as set forth in claim 1, further comprising a second metal layer formed on the first metal layer in order to increase reflectivity of light emitted from the optical element.

3. The package substrate as set forth in claim 1, further comprising a lens part formed on the fluorescent resin material in order to protect the optical element.

4. The package substrate as set forth in claim 1, wherein the metal core comprises aluminum (Al), an aluminum alloy, or copper (Cu).

5. The package substrate as set forth in claim 1, wherein the insulating layer comprises either aluminum oxide (Al₂O₃) or epoxy.

6. The package substrate as set forth in claim 1, wherein the first metal layer comprises:
a wiring pattern on which the optical element is mounted;
a first electrode pattern integrated with the wiring pattern so as to be electrically connected to the optical element; and
a second electrode pattern insulated from the wiring pattern so as to be electrically connected to the optical element.

7. The package substrate as set forth in claim 6, wherein the first metal layer further comprises a trench formed around the wiring pattern so as to form a thickness difference around the wiring pattern.

8. A method of manufacturing a package substrate for an optical element, comprising:
(A) forming a hole in a metal core;
(B) forming an insulating layer on a surface of the metal core having the hole formed therein;
(C) forming a first metal layer on a surface of the insulating layer to include a trench and a circuit layer comprising a wiring pattern, a first electrode pattern and a second electrode pattern so as to include therein the metal core insulated by the insulating layer; and
(D) mounting the optical element on the circuit layer and then applying a fluorescent resin material on the optical element.

9. The method as set forth in claim 8, further comprising (E) forming a second metal layer on the first metal layer.

10. The method as set forth in claim 8, further comprising (F) forming a lens part on the fluorescent resin material in order to protect the optical element.

11. The method as set forth in claim 8, wherein (B) is performed by anodizing the surface of the metal core thus forming the insulating layer on the surface of the metal core.

12. The method as set forth in claim 8, wherein (B) is performed by adhering epoxy on the surface of the metal core using an adhesive thus forming the insulating layer on the surface of the metal core.

13. The method as set forth in claim 8, wherein (C) comprises:
(C-1) forming a seed layer on the surface of the insulating layer using nickel (Ni), titanium (Ti), zinc (Zn), chromium (Cr) or copper (Cu), and then applying copper (Cu) on the seed layer thus forming the first metal layer; and
(C-2) bringing a dry film resist into close contact with the first metal layer, performing exposure and development, and then performing primary etching such that a region of the first metal layer around the wiring pattern is half-etched to create the trench, thus forming the circuit layer comprising the wiring pattern, the first electrode pattern and the second electrode pattern which are integrated with each other.

14. The method as set forth in claim 13, wherein (C-2) further comprises performing secondary etching for etching a portion of the first metal layer until the insulating layer is exposed so that at least one of the first electrode pattern and the second electrode pattern is insulated from the wiring pattern.

15. The method as set forth in claim 8, wherein (D) comprises:
mounting the optical element on the wiring pattern;
flip-chip bonding the wiring pattern to an electrode located on a lower surface of the optical element;
wire-bonding the at least one of the first electrode pattern and the second electrode pattern, which is insulated from the wiring pattern, to an electrode located on an upper surface of the optical element; and
applying the fluorescent resin material on the optical element in order to protect the optical element.
